(19) United States
(12) Patent Application Publication
(10) Pub. No.: US 2026/0068362 A1
(43) Pub. Date: Mar. 5, 2026

(54) LIGHT EMITTING DIODE AND LIGHT EMITTING MODULE HAVING THE SAME

(71) Applicant: SEOUL VIOSYS CO., LTD., Ansan-si (KR)

(72) Inventor: Jaekwon KIM, Ansan-si (KR)

(73) Assignee: SEOUL VIOSYS CO., LTD., Ansan-si (KR)

(21) Appl. No.: 19/276,102

(22) Filed: Jul. 22, 2025

Related U.S. Application Data
(60) Provisional application No. 63/673,847, filed on Jul. 22, 2024.
(60) Provisional application No. 63/719,001, filed on Nov. 11, 2024.

(51) Int. Cl. H10H 20/819; H10H 29/855

(52) U.S. Cl. CPC H10H 20/819; H10H 29/855

(57) ABSTRACT

A light emitting apparatus includes a plurality of light emitting cells disposed apart from one another on a substrate; and a first electrode and a second electrode connected to the plurality of light emitting cells.

### TECHNICAL FIELD

The present disclosure relates to a light emitting apparatus and a light emitting module having the same.

### BACKGROUND ART

A light emitting diode (LED) is one type of light emitting devices that emit light when current is applied. Recently, the light emitting diode has been widely used in various technical fields such as a display apparatus, a vehicle lamp, and general lighting applications. The light emitting diode has advantages of long service life, low power consumption, and fast response speed. By taking full advantage of these features, the light emitting diode has rapidly replaced conventional light sources. As an example, a display apparatus using light emitting diodes can be achieved by forming a structure of individually grown red (R), green (G), and blue (B) light emitting diodes (LEDs) on a final substrate.

Specifically, the light emitting diode is formed by epitaxially growing layers on a substrate, and includes an n-type semiconductor layer, a p-type semiconductor layer, and an active layer interposed therebetween. An n-electrode pad is formed on the n-type semiconductor layer, and a p-electrode pad is formed on the p-type semiconductor layer, thereby allowing the light emitting diode to be driven by being electrically connection to an external power source through the electrode pads. In this case, current can flow from the p-electrode pad through the semiconductor layers to the n-electrode pad, and light emitted through the recombination of electrons and holes in the active layer can be emitted.

### DISCLOSURE

### Technical Problem

The present disclosure aims to provide a light emitting apparatus and a light emitting module including the same capable of controlling a matrix-shaped light-emitting pattern.

The present disclosure aims to provide a light emitting apparatus and a light emitting module including the same capable of forming a plurality of light-emitting regions surrounded by non-light-emitting regions and of normally operating even when some of the light-emitting regions are defective.

The present disclosure aims to provide a light emitting apparatus and a light emitting module including the same capable of preventing a light emitting cell from being broken and failing to emit light.

The present disclosure aims to provide a light emitting apparatus and a light emitting module including the same capable of relieving stress applied to an insulation layer disposed on a light-emitting region, which is an upper surface region of a light emitting cell, and of preventing ingress of moisture caused by peeling of the insulation layer.

The present disclosure aims to provide a light emitting apparatus and a light emitting module including the same capable of preventing a light emitting cell from tilting due to a center of gravity of the light emitting cell being tilted to a side of the light emitting cell.

The present disclosure aims to provide a light emitting apparatus and a light emitting module including the same capable of preventing a finger electrode from breaking, by increasing a flexibility of the finger electrode covering a light emitting cell with respect to heat generated from the light emitting cell.

The present disclosure aims to provide a light emitting apparatus and a light emitting module including the same capable of preventing a semiconductor layer of a light emitting cell from being exposed and oxidized between an edge of a finger electrode covering a light-emitting region, which is an upper surface region of the light emitting cell, and an opening of an insulation layer.

The present disclosure aims to provide a light emitting apparatus and a light emitting module including the same capable of preventing a side of a light emitting apparatus disposed on a substrate from being lifted, by disposing a first electrode and a second electrode of the light emitting apparatus on opposite sides with respect to light emitting cells.

The present disclosure aims to provide a light emitting apparatus and a light emitting module including the same capable of preventing luminous intensity from being concentrated on a particular light emitting cell, by uniformly supplying current to semiconductor layers of light emitting cells.

The present disclosure aims to provide a light emitting apparatus and a light emitting module including the same capable of reducing overheating of an electrode due to a large difference in current injection amount caused by a difference in resistance, by making a width of a second finger electrode connected to a first conductivity type semiconductor layer having a relatively low resistance smaller than a width of a first finger electrode connected to a second conductivity type semiconductor layer having a relatively high resistance.

The present disclosure aims to provide a light emitting apparatus and a light emitting module including the same capable of increasing light extraction efficiency with light refraction by a side region of a light emitting cell covered with a plurality of insulation materials.

The present disclosure aims to provide a light emitting apparatus and a light emitting module including the same also capable of performing a function of a lens that extracts light to the outside by gradually narrowing a width of a light emitting cell in a thickness direction.

The present disclosure aims to provide a light emitting apparatus and a light emitting module including the same capable of reducing a driving voltage and heat generation.

The present disclosure aims to provide a light emitting apparatus and a light emitting module including the same capable of preventing an electrode electrically connected to a light emitting cell from being short-circuited even when a substrate contracts or expands.

The present disclosure aims to provide a light emitting apparatus and a light emitting module including the same capable of improving current spreading to a light emitting cell.

The present disclosure aims to provide a light emitting apparatus and a light emitting module including the same capable of preventing excessive electron generation, thereby preventing leakage current generation and increasing resistance.

The present disclosure aims to provide a light emitting apparatus and a light emitting module including the same capable of reducing light loss, preventing light interference, and increasing light extraction efficiency through light reflection, light refraction, and light path guide.

The present disclosure aims to provide a light emitting apparatus and a light emitting module including the same capable of increasing heat dissipation efficiency and heat dissipation performance.

The present disclosure aims to provide a light emitting apparatus and a light emitting module including the same capable of preventing moisture ingress into light emitting cells and increasing bonding strength between adjacent light emitting cells.

### Technical Solution

A light emitting apparatus according to an embodiment of the present disclosure includes a plurality of light emitting cells disposed apart from one another on a substrate, and a first electrode and a second electrode connected to the plurality of light emitting cells.

In an embodiment, the light emitting cell may be a mesa including an active layer that generates light.

In an embodiment, a length of a side of a light-emitting region provided on an upper surface of the light emitting cell may be 2 to 50 times of a height of the light emitting cell.

In an embodiment, the plurality of light emitting cells is disposed in an M×N matrix pattern (M and N are natural numbers), and each of them may be surrounded by a non-light-emitting region.

In an embodiment, a first insulation layer disposed over the plurality of light emitting cells may be further included.

In an embodiment, the first insulation layer may include a first opening disposed on the light-emitting region.

In an embodiment, the first insulation layer may further include a second opening disposed on the non-light-emitting region.

In an embodiment, the first electrode may extend over upper portions of the light-emitting regions and be electrically connected to the light emitting cell through the first opening.

In an embodiment, the second electrode may be electrically connected to the light emitting cell through the second opening.

In an embodiment, the second electrode may include a second finger electrode extending between the light emitting cells.

In an embodiment, the first finger electrode may extend in a first direction parallel to a side of the substrate in a plan view.

In an embodiment, the second finger electrode may extend in the first direction parallel to a side of the substrate on the flat surface.

In an embodiment, the first finger electrode and the second finger electrode may be alternately disposed along a second direction perpendicular to the first direction.

In an embodiment, the first electrode may further include a first connection electrode disposed at one end of the first direction and connected to the first finger electrode.

In an embodiment, the second electrode may further include a second connection electrode disposed at the other end of the first direction and connected to the second finger electrode.

In an embodiment, the first opening may be formed at a position overlapping an intersection point where two diagonals connecting vertices of the light-emitting region intersect.

In an embodiment, a width of the first finger electrode may be equal to or greater than a diameter of the first opening.

In an embodiment, the width of the first finger electrode may be 0.4 times or less of that of the light-emitting region.

In an embodiment, a second insulation layer disposed over the first insulation layer may be further included.

In an embodiment, the second insulation layer may include a first opening exposing a portion of the first electrode.

In an embodiment, a first electrode pad connected to the first electrode through the first opening may be further included.

In an embodiment, an ohmic electrode disposed over the light emitting cell may be further included.

In an embodiment, the first finger electrode may be formed in a mesh shape passing over the upper portions of the light-emitting regions.

In an embodiment, the first electrode may include a plurality of first electrode pads connected to the first finger electrode.

In an embodiment, the first finger electrode may further include a blocking region configured to block electrical connection between adjacent light emitting cells.

A light emitting apparatus according to an embodiment of the present disclosure includes a plurality of light emitting cells disposed apart from one another; and a first electrode and a second electrode connected to the plurality of light emitting cells, in which the first electrode may include a blocking region configured to block electrical connection between adjacent light emitting cells.

### Advantageous Effects

The present disclosure may provide a light emitting apparatus and a light emitting module including the same capable of controlling a matrix-shaped light-emitting pattern.

The present disclosure may provide a light emitting apparatus and a light emitting module including the same capable of forming a plurality of light-emitting regions surrounded by non-light-emitting regions and of normally operating even when some of the light-emitting regions are defective.

The present disclosure may provide a light emitting apparatus and a light emitting module including the same capable of preventing a light emitting cell from being broken and failing to emit light.

The present disclosure may provide a light emitting apparatus and a light emitting module including the same capable of relieving stress applied to an insulation layer disposed on a light-emitting region, which is an upper surface region of a light emitting cell, and of preventing ingress of moisture caused by peeling of the insulation layer.

The present disclosure may provide a light emitting apparatus and a light emitting module including the same capable of preventing a light emitting cell from tilting due to a center of gravity of the light emitting cell being tilted to a side of the light emitting cell.

The present disclosure may provide a light emitting apparatus and a light emitting module including the same capable of preventing a finger electrode from breaking, by increasing a flexibility of the finger electrode covering a light emitting cell with respect to heat generated from the light emitting cell.

The present disclosure may provide a light emitting apparatus and a light emitting module including the same capable of preventing a semiconductor layer of a light emitting cell from being exposed and oxidized between an edge of a finger electrode covering a light-emitting region, which is an upper surface region of the light emitting cell, and an opening of an insulation layer.

The present disclosure may provide a light emitting apparatus and a light emitting module including the same capable of preventing a side of a light emitting apparatus disposed on a substrate from being lifted, by disposing a first electrode and a second electrode of the light emitting apparatus on opposite sides with respect to light emitting cells.

The present disclosure may provide a light emitting apparatus and a light emitting module including the same capable of preventing luminous intensity from being concentrated on a particular light emitting cell, by uniformly supplying current to semiconductor layers of light emitting cells.

The present disclosure may provide a light emitting apparatus and a light emitting module including the same capable of reducing overheating of an electrode due to a large difference in current injection amount caused by a difference in resistance, by making a width of a second finger electrode connected to a first conductivity type semiconductor layer having a relatively low resistance smaller than a width of a first finger electrode connected to a second conductivity type semiconductor layer having a relatively high resistance.

The present disclosure may provide a light emitting apparatus and a light emitting module including the same capable of increasing light extraction efficiency with light refraction by a side region of a light emitting cell covered with a plurality of insulation materials.

The present disclosure may provide a light emitting apparatus and a light emitting module including the same also capable of performing a function of a lens that extracts light to the outside by gradually narrowing a width of a light emitting cell in a thickness direction.

The present disclosure may provide a light emitting apparatus and a light emitting module including the same capable of reducing a driving voltage and heat generation.

The present disclosure may provide a light emitting apparatus and a light emitting module including the same capable of preventing an electrode electrically connected to a light emitting cell from being short-circuited even when a substrate shrinks or expands.

The present disclosure may provide a light emitting apparatus and a light emitting module including the same capable of improving current spreading to a light emitting cell.

The present disclosure may provide a light emitting apparatus and a light emitting module including the same capable of preventing excessive electron generation, thereby preventing leakage current generation and increasing resistance.

The present disclosure may provide a light emitting apparatus and a light emitting module including the same capable of reducing light loss, preventing light interference, and increasing light extraction efficiency through light reflection, light refraction, and light path guide.

The present disclosure may provide a light emitting apparatus and a light emitting module including the same capable of increasing heat dissipation efficiency and heat dissipation performance.

The present disclosure may provide a light emitting apparatus and a light emitting module including the same capable of preventing moisture ingress into light emitting cells and increasing bonding strength between adjacent light emitting cells.

### DESCRIPTION OF DRAWINGS

FIG. 1 is a schematic plan view of a light emitting module according to an embodiment of the present disclosure.

FIG. 2 is a plan view illustrating a light emitting apparatus according to an embodiment of the present disclosure.

FIG. 3 is a real image illustrating the light emitting apparatus of FIG. 2.

FIG. 4A is a cross-sectional view taken along line I-I′ of FIG. 2.

FIG. 4B is a conceptual diagram illustrating a portion of a configuration of FIG. 4A.

FIG. 4C is a plan view of FIG. 4B.

FIG. 5 is a modified example of FIG. 4A.

FIG. 6A is a plan view illustrating a light emitting apparatus according to another embodiment of the present disclosure.

FIG. 6B is a plan view illustrating a light emitting apparatus according to another embodiment of the present disclosure.

FIG. 7A is a diagram illustrating a light emitting apparatus in which all light emitting cells are capable of normal operation, FIG. 7B is a diagram illustrating a light emitting state of a corresponding light emitting apparatus, and FIG. 7C is a diagram illustrating a blocking region between two light emitting cells.

FIG. 8A is a diagram illustrating a light emitting apparatus in which some of light emitting cells are defective, and FIG. 8B is a diagram illustrating a light emitting state of a corresponding light emitting apparatus.

FIG. 9A is a diagram illustrating a light emitting apparatus in which some of light emitting cells are defective, and FIG. 9B is a diagram illustrating a light emitting state of a corresponding light emitting apparatus.

FIG. 10 is a graph showing luminous intensity spectrums of the light emitting apparatuses of FIG. 7A, FIG. 8A, and FIG. 9A.

FIG. 11 is a graph showing EQEs of the light emitting apparatuses of FIG. 7A, FIG. 8A, and FIG. 9A.

FIG. 12 is a plan view illustrating a light emitting module according to another embodiment of the present disclosure.

FIG. 13 is a cross-sectional view in a direction II-I′ of FIG. 12.

FIG. 14 is a modified example of a light emitting apparatus of FIG. 12.

FIG. 15 is a conceptual diagram illustrating an electrode connection method of the light emitting apparatus of FIG. 14.

FIG. 16 is a plan view illustrating a light emitting module according to another embodiment of the present disclosure.

FIG. 17 is a cross-sectional view of a light emitting apparatus of FIG. 16.

FIG. 18 is a top view of a light emitting apparatus according to another embodiment of the present disclosure.

FIG. 19 is a cross-sectional view in a direction I-I′ of FIG. 18.

FIG. 20 is a cross-sectional view in a direction II-II′ of FIG. 18.

### DETAILED DESCRIPTION OF THE ILLUSTRATED EMBODIMENTS

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or redisposed without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, or others, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting apparatus of the present disclosure and a light emitting module including the same will be described in detail through the accompanying drawings.

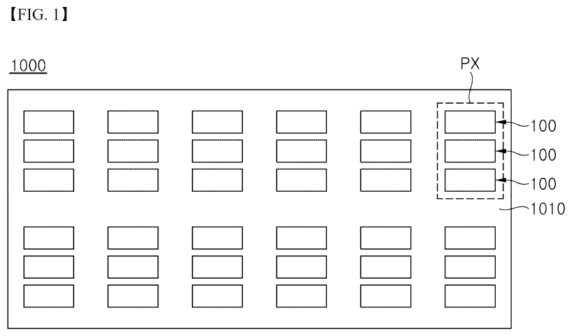

Referring to FIG. 1, a light emitting apparatus 100 of the present disclosure may be provided in one or more numbers to form one light emitting module 1000.

Specifically, the light emitting module 1000 may include a substrate 1010 and a plurality of light emitting apparatuses 100 disposed on the substrate 1010. The substrate 1010 may be a circuit board, a light-transmitting substrate, a glass substrate, a TFT substrate, a polymer substrate, a flexible substrate, a polyimide substrate, or others, without being limited to a particular substrate. The substrate 1010 may be formed with an area larger than that of the light emitting apparatus 100.

The light emitting apparatus 100 may be formed in a polygonal shape in a plan view, and may be, for example, formed in a square shape. A length of a side of the light emitting apparatus 100 may be 200 μm or less. The area of the light emitting apparatus 100 may be 40,000 μm² or less.

The light emitting apparatus 100 may be provided in a plurality of numbers, and the plurality of light emitting apparatuses 100 may be grouped to form one group PX. The one group PX may emit light having a single color or a single peak wavelength. Alternatively, the one group PX may emit light having a plurality of colors or a plurality of peak wavelengths. Light having the plurality of colors or the plurality of peak wavelengths may be formed by making peak wavelengths of lights emitted from the plurality of light emitting apparatuses 100 different from one another, or by disposing a wavelength conversion material over the light emitting apparatus 100.

The light emitting apparatus 100 may include a plurality of light emitting cells 130 disposed apart from one another on a substrate 110, and a first electrode 160 and a second electrode 170 connected to the plurality of light emitting cells 130.

The substrate 110 is a substrate on which the light emitting cells 130 are disposed and is not limited to a particular substrate. For example, the substrate 110 may include a heterogeneous substrate such as a sapphire substrate, a gallium arsenide substrate, a silicon substrate, a silicon carbide substrate, or a spinel substrate, and in addition, may include a homogeneous substrate such as a gallium nitride substrate, an aluminum nitride substrate, or the like. The substrate 110 may include a conductive pattern, and the conductive pattern may be disposed over the substrate 110, may be disposed within the substrate 110, or may pass through the substrate 110.

The light emitting apparatus 100 may further include a first conductivity type semiconductor layer 120 disposed on the substrate 110. The first conductivity type semiconductor layer 120 may include a phosphide or nitride semiconductor such as (Al, Ga, In)P or (Al, Ga, In)N, and may be disposed on the substrate using a method such as MOCVD, MBE, HVPE, or the like. In addition, the first conductivity type semiconductor layer 120 may be doped as n-type by including one or more impurities such as Si, C, Ge, Sn, Te, Pb, or the like. However, the inventive concepts are not limited thereto, and the first conductivity type semiconductor layer 120 may be doped with an opposite conductive type including a p-type dopant.

The light emitting cells 130 may be a light emitting structure disposed apart from one another on the substrate 110. The light emitting cell 130 may be a mesa formed protrudingly on the substrate 110.

The light emitting cell 130 may include the first conductivity type semiconductor layer 120, an active layer 121, and a second conductivity type semiconductor layer 123.

A portion of the first conductivity type semiconductor layer 120 disposed on the substrate 110 may be included in the mesa of the light emitting cell 130.

The active layer 121 may be a light emitting layer disposed over the first conductivity type semiconductor layer 120. The active layer 121 is the light emitting layer formed over the first conductivity type semiconductor layer 120, may include a phosphide or nitride semiconductor such as (Al, Ga, In)P or (Al, Ga, In)N, and may be grown on the first conductivity type semiconductor layer 120 using a technique such as MOCVD, MBE, HVPE, or the like. In addition, the active layer 121 may include a quantum well structure (QW) including at least two barrier layers and at least one well layer, and moreover, may include a multi quantum well structure (MQW) including a plurality of barrier layers and a plurality of well layers. A wavelength of light emitted from the active layer 121 may be adjusted by controlling a composition ratio of materials forming the well layer.

The second conductivity type semiconductor layer 123 may be a semiconductor layer disposed on the active layer 121. The second conductivity type semiconductor layer 123 may include a phosphide or nitride semiconductor such as (Al, Ga, In)P or (Al, Ga, In)N, and may be grown using a technique such as MOCVD, MBE, HVPE, or the like. The second conductivity type semiconductor layer 123 may be doped with a conductive type opposite to that of the first conductivity type semiconductor layer 120. For example, the second conductivity type semiconductor layer 123 may be doped as a p-type by including an impurity such as Mg.

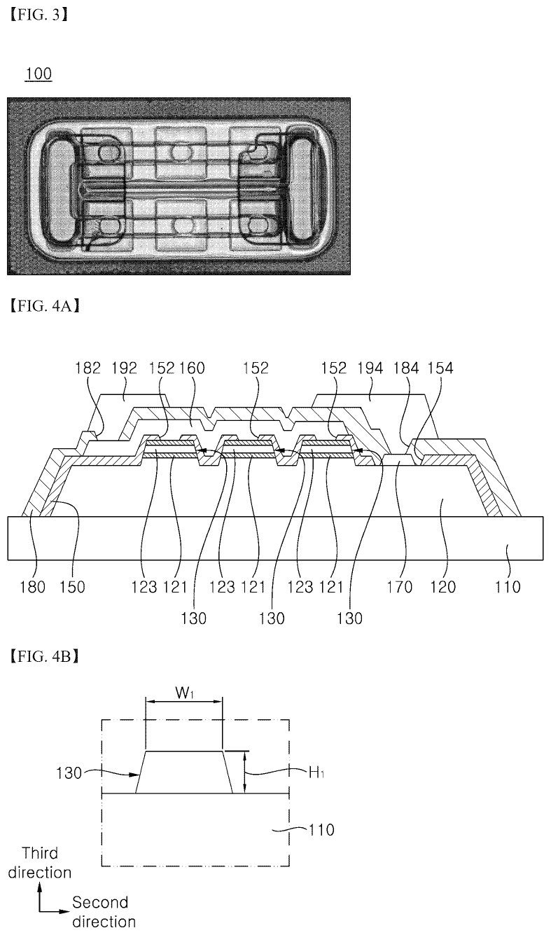

Referring to FIGS. 4B and 4C, the light emitting cell 130 is a mesa having a height H1, and a light-emitting region ER may be provided on an upper surface thereof. A corner of the light emitting cell 130 may have a curvature. Accordingly, light may be prevented from being concentrated at the corner of the light emitting cell 130, so that light may be emitted uniformly throughout an entire light emitting cell 130.

The height H1 of the light emitting cell 130 may be 1 to 2 μm.

The light-emitting region ER may be formed in a polygonal shape on a flat surface, and may be, for example, formed in a square shape. A length W1 or W2 of a side of the light-emitting region ER may be 2 to 50 times of the height H1 of the light emitting cell 130. That is, H1:W1 or H1:W2 may have a ratio of a:b. When a is 1, b may be greater than or equal to 2 and less than or equal to 50. Accordingly, a center of gravity of the light emitting cell 130 is formed low, and thus, even when an area of the light-emitting region ER becomes small, the light emitting cell 130 may be prevented from being broken and turned off.

Table 1 below shows defect rates (%) and EQEs (%) when the length of a side W1 or W2 of the light-emitting region ER is changed with respect to the height H1 of the light emitting cell 130.

TABLE 1

| H1(μm) | W1 or W2 (μm) | a:b | Defect rate (%) | EQE(%) |
|---|---|---|---|---|
| 1 | 0.5 | 1:0.5 | 23 | 9.1 |
| 1 | 1 | 1:1 | 20 | 10.4 |
| 1 | 2 | 1:2 | 9 | 12.5 |
| 1 | 5 | 1:5 | 12 | 12.4 |
| 1 | 10 | 1:10 | 10 | 12.6 |
| 1 | 20 | 1:20 | 11 | 12.8 |
| 1 | 30 | 1:30 | 9 | 12.7 |
| 1 | 40 | 1:40 | 12 | 12.8 |
| 1 | 50 | 1:50 | 10 | 12.6 |
| 1 | 60 | 1:60 | 18 | 9.5 |
| 1 | 70 | 1:70 | 30 | 7.8 |
| 1 | 80 | 1:80 | 48 | 6.9 |
| 1 | 90 | 1:90 | 57 | 5.3 |
| 1 | 100 | 1:100 | 63 | 4.1 |

When the lengths W1 or W2 of a side of the light-emitting region ER are in a range of 2 to 50 times of the height H1 of the light emitting cell 130, it can be seen that the defect rates (%) are maintained at 10% or less, so that the defect rates (%) are maintained at a low level. In addition, when the lengths W1 or W2 of a side of the light-emitting region ER are in the range of 2 to 50 times of the height H1 of the light emitting cell 130, it can be seen that the EQEs (External Quantum Efficiency) are maintained at a relatively high level, thereby increasing luminous efficiency.

The plurality of light emitting cells 130 is disposed in an M×N matrix pattern (M and N are natural numbers), and at least a partial region thereof may be surrounded by a non light-emitting region, respectively. Herein, the non light-emitting region may be a region excluding the light-emitting region ER that is an upper surface region of the light emitting cell 130 on a flat surface.

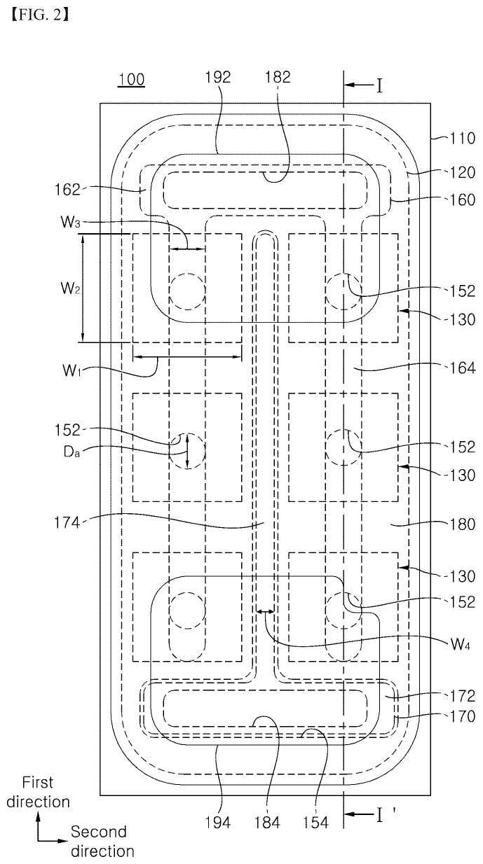

As an example, FIG. 2 illustrates an example in which six light emitting cells 130 are disposed in a 2×3 matrix pattern on a flat surface parallel to a first direction and a second direction perpendicular to the first direction. A number or an arrangement pattern of the light emitting cells 130 is not limited thereto. For example, it is also possible to dispose 28 light emitting cells 130 in a 4×7 matrix pattern as in FIG. 6A, or to dispose 9 light emitting cells 130 in a 3×3 matrix pattern as in FIG. 6B.

The light emitting apparatus 100 may further include an ohmic electrode 140 disposed over the light emitting cell 130.

The ohmic electrode 140 is a layer formed in a size corresponding to or smaller than that of the light-emitting region ER, and may distinguish the light-emitting region ER. The ohmic electrodes 140 may be disposed on the upper surface of each of the light emitting cells 130 to be spaced apart from one another. Accordingly, the ohmic electrodes 140 may also be disposed in the M×N matrix pattern (M and N are natural numbers).

The light emitting apparatus 100 may further include a first insulation layer 150 disposed over the plurality of light emitting cells 130.

The first insulation layer 150 is an insulation layer that covers the light-emitting region ER and the non light-emitting region, and may be disposed over the ohmic electrode 140. The first insulation layer 150 may include a first opening 152 disposed on the light-emitting region ER.

The first opening 152 may be disposed in at least one per light-emitting region ER. A portion of the ohmic electrode 140 may be exposed through the first opening 152.

The first opening 152 may be formed in various shapes, and may be different from the shape of the light-emitting region ER. Accordingly, by making a distance of the first insulation layer 150 from a boundary of the light-emitting region ER to the first opening 152 vary, a stress applied to the first insulation layer 150 may be alleviated, and it is possible to prevent the first insulation layer 150 from peeling off near the first opening 152 and moisture from infiltrating.

For example, the first opening 152 may be a circular opening as illustrated in FIG. 2. A diameter Da of the first opening 152 may be formed in various sizes, but may be less than or equal to the length W1 or W2 of a side of the light-emitting region ER. More preferably, the diameter Da of the first opening 152 may be 0.5 times or less of a side length W1 or W2 of the light-emitting region ER.

Referring to FIG. 4C, the first opening 152 may be formed at a position overlapping an intersection point CR where two diagonals L1 and L2 connecting vertices of the light-emitting region ER intersect. Accordingly, the light emitting cell 130 may be prevented from being tilted due to a center of gravity of the light emitting cell 130 being tilted to a side of the light emitting cell 130.

A center point of the first opening 152 may coincide with or be spaced apart from the intersection point CR.

As the first opening 152 forms a region with a low light absorption rate, the luminous efficiency may be increased at the center of the light-emitting region ER. In addition, current may be uniformly injected into the light-emitting region ER through the first opening 152.

The first insulation layer 150 may further include a second opening 154 disposed on the non-light-emitting region. The first conductivity type semiconductor layer 120 on the non-light-emitting region may be exposed through the second opening 154.

The first electrode 160 and the second electrode 170 may be electrodes connected to the plurality of light emitting cells 130.

First, the first electrode 160 may be disposed on the first insulation layer 150 and connected to the second conductivity type semiconductor layer 123 of the light emitting cell 130 through the first opening 152.

As illustrated in FIG. 2, the first electrode 160 may include a first finger electrode 164 that passes over upper portions of the light-emitting regions ER and is electrically connected to the light emitting cell 130 through the first opening 152.

The first finger electrode 164 may be an extension electrode extending in a first direction parallel to a side of the substrate 110 on a flat surface. An extension direction of the first finger electrode 164 may coincide with the first direction in which the light emitting cells 130 covered by the first finger electrode 164 are arranged.

The first finger electrode 164 may be formed as a single unit, or when the light emitting cells 130 are disposed in a plurality of rows, the first finger electrode 164 may also be provided in a plurality of units. The plurality of finger electrodes 164 may be disposed in parallel along a second direction perpendicular to the first direction.

The first finger electrode 164 may extend past the upper surface of the light emitting cell 130 to another adjacent light emitting cell 130 and may have a width W3 (second direction length) perpendicular to the extension direction.

The first finger electrode 164 is an electrode that extends over the upper surface of the light emitting cells 130. A portion of the first finger electrode 164 may be disposed on the upper surface of the light emitting cells 130, while another portion may cover side surfaces of the light emitting cells 130 along the first direction. Accordingly, the first finger electrode 164 supports the side surfaces of the light emitting cells 130 arranged in the first direction, thereby preventing the light emitting cells 130 from tilting in the first direction and causing a short circuit.

The width W3 of the first finger electrode 164 may be 0.4 times or less of the width W1 of the light-emitting region ER. In addition, the first finger electrode 164 may be formed in a thin thickness. Accordingly, the first finger electrode 164 may be easily extended and formed in a close state, and a flexibility of the first finger electrode 164 may be increased with respect to heat generated from the light emitting cell 130, thereby preventing the first finger electrode 164 from being broken.

In addition, the width W3 of the first finger electrode 164 may be equal to or greater than the diameter Da of the first opening 152. Accordingly, the second conductivity type semiconductor layer 123 may be prevented from being exposed and oxidized between an edge of the first finger electrode 164 and the first opening 152.

The first electrode 160 may further include a first connection electrode 162 disposed at one end of the first direction and connected to the first finger electrode 164. The first connection electrode 162 may be a central electrode connected to the first finger electrodes 164 as a main electrode. The first electrode 160 is disposed on an opposite side of the second electrode 170 with respect to the light emitting cells 130, which will be described later, thereby maintaining balance, and thus, it is possible to prevent a side of the light emitting apparatus 100 disposed on the substrate 1010 of the light emitting module 1000 from being lifted.

The second electrode 170 may be electrically connected to the light emitting cell 130 through the second opening 154. The second electrode 170 may be connected to the first conductivity type semiconductor layer 120 exposed through the second opening 154 of the first insulation layer 150.

The second electrode 170 may include a second finger electrode 174 extending between the light emitting cells 130.

The second finger electrode 174 may be an extension electrode extending in a first direction parallel to a side of the substrate 110 on a flat surface. The first direction may be parallel to the first direction in which the light emitting cells 130 connected to one first finger electrode 164 are arranged. Accordingly, by keeping the distance between the side surfaces of the light emitting cells 130 and the second finger electrode 174 parallel, current may be uniformly supplied to the first conductivity type semiconductor layer 120 included in the light emitting cells 130, thereby preventing luminous intensity from being concentrated on a particular light emitting cell 130.

When the light emitting cells 130 are disposed in a plurality of rows, the second finger electrodes 174 may also be provided in a plurality of rows. The plurality of second finger electrodes 174 may be disposed in parallel along a second direction perpendicular to the first direction.

The second finger electrode 174 may extend in the first direction between adjacent light emitting cells 130, and may have a width W4 perpendicular to an extension direction.

The second finger electrode 174 is an electrode that crosses between the light emitting cells 130 arranged in the first direction, and a portion of the second finger electrode 174 may be disposed between the light emitting cells 130 arranged in the second direction.

The width W4 of the second finger electrode 174 may be smaller than the width W3 of the first finger electrode 164. By making the width W4 of the second finger electrode 174 electrically connected to the first conductivity type semiconductor layer 120 having a lower resistance smaller than the width W3 of the first finger electrode 164 electrically connected to the second conductivity type semiconductor layer 123 having a relatively higher resistance, it is possible to reduce overheating of the electrode due to a difference in amount of current injected caused by a difference in resistance.

The second finger electrode 174 is an electrode disposed in the non-light-emitting region, and when not turned on in the light-emitting region ER, rows in which the light emitting cells 130 are disposed may be clearly distinguished by the second finger electrode 174.

The width W4 of the second finger electrode 174 in the second direction perpendicular to the first direction may be less than half of the length W1 or W2 of a side of the light-emitting region ER. Accordingly, when the light-emitting regions ER are turned on, the boundary between the light-emitting regions ER does not appear distinct and a plurality of light-emitting regions ER may be made to appear as one light-emitting region.

One end of the second finger electrode 174 may extend to a same line as a boundary of the light emitting cell 130 disposed at an outermost portion on the substrate 110, or may extend beyond the boundary of the light emitting cell 130. Through this, current may be supplied evenly to each of the light emitting cells 130, and it is possible to prevent current from being excessively concentrated in a particular region.

In addition, the first finger electrode 164 and the second finger electrode 174 may be alternately disposed along the second direction perpendicular to the first direction.

The first finger electrode 164 and the second finger electrode 174 may increase light extraction efficiency by reflecting light when the light-emitting region ER is turned on.

The second electrode 170 may further include a second connection electrode 172 that is disposed at the other end in the first direction and connected to the second finger electrode 174. The second connection electrode 172 may be a central electrode connected to the second finger electrodes 174 as a main electrode.

The second connection electrode 172 may be disposed at an end opposite to the first connection electrode 162 with the light emitting cells 130 interposed therebetween. Accordingly, it is possible to prevent a side of the light emitting apparatus 100 disposed on the substrate 1010 in the light emitting module 1000 from being lifted.

That is, the first connection electrode 162 may be disposed at one end in the first direction and the second connection electrode 172 may be disposed at the other end in the first direction, but this is only exemplary and the first connection electrode 162 and the second connection electrode 172 may be disposed at various positions on the non-light-emitting region.

The light emitting apparatus 100 may further include a second insulation layer 180 disposed over the first insulation layer 150.

The second insulation layer 180 may be an insulation layer covering the first electrode 160 and the second electrode 170. The second insulation layer 180 may include a first opening 182 that exposes a portion of the first electrode 160.

The first opening 182 of the second insulation layer 180 may be formed on the first connection electrode 162 of the first electrode 160. A portion of the first connection electrode 162 may be exposed through the first opening 182. A region of the side surface of the light emitting cell 130 covered with an insulation material maybe increased by disposing the first opening 182 at a position spaced apart from the light emitting cell 130, and the light extraction efficiency may be increased due to light refraction by the side surface region of the light emitting cell 130 covered with a plurality of insulation materials.

The light emitting apparatus 100 may further include a first electrode pad 192 electrically connected to the first electrode 160 through the first opening 182. The light emitting apparatus 100 may be electrically connected to the substrate 1010 through the first electrode pad 192.

The second insulation layer 180 may include a second opening 184 that exposes a portion of the second electrode 170.

The second opening 184 of the second insulation layer 180 may be formed on the second connection electrode 172 of the second electrode 170. The portion of the second connection electrode 172 may be exposed through the second opening 184.

The light emitting apparatus 100 may further include a second electrode pad 194 electrically connected to the second electrode 170 through the second opening 184. The light emitting apparatus 100 may be electrically connected to the substrate 1010 through the second electrode pad 194.

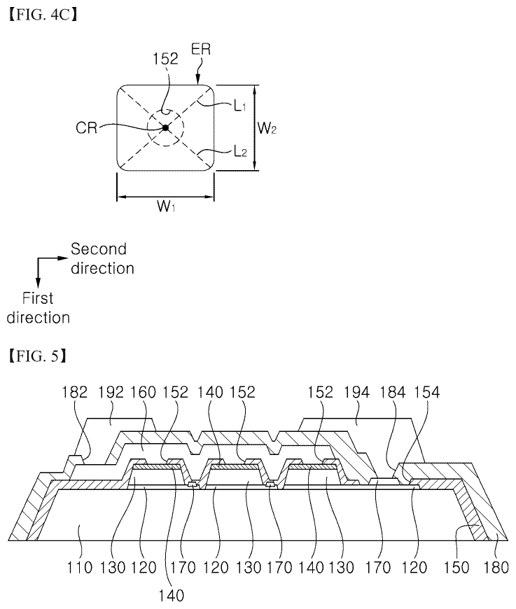

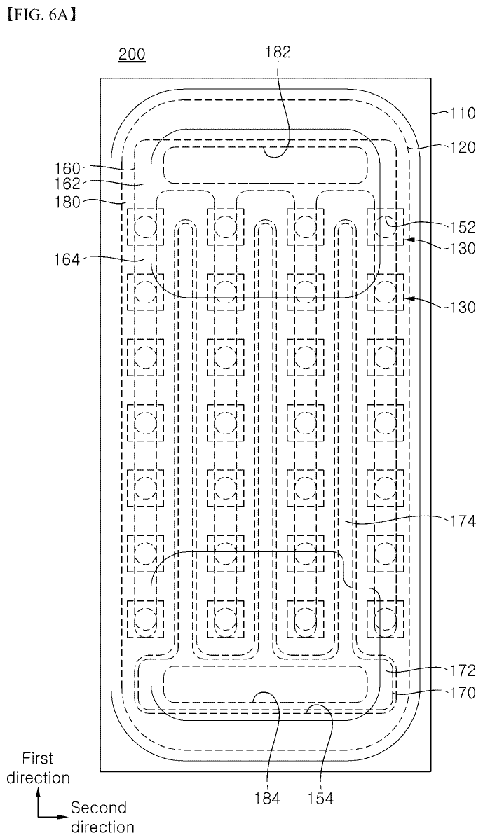

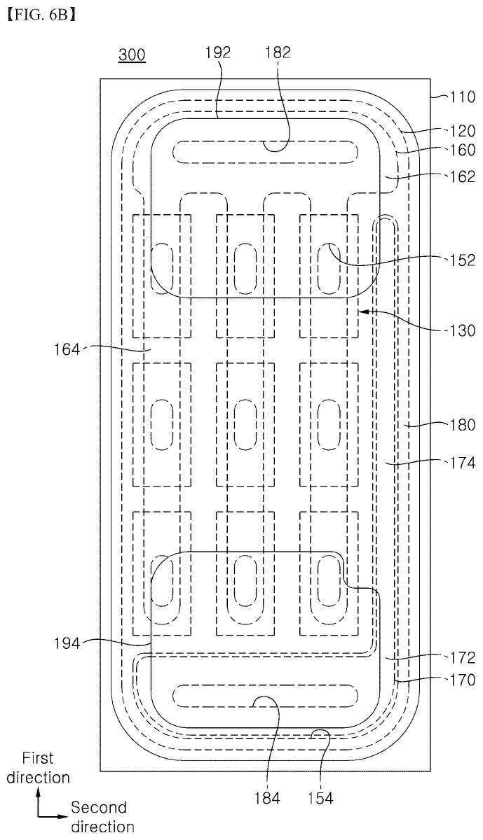

Next, FIG. 5 is a modified example of the light emitting apparatus 100 of FIGS. 2 through 4C, which may be configured identically or similarly to the light emitting apparatus 100 of FIGS. 2 through 4C, except that a first conductivity type semiconductor layer 120 is an isolated structure for each of light emitting cells 130.

In a case of the light emitting apparatus 100 of FIGS. 2 through 4C, it has a shape that the first conductivity type semiconductor layer 120 is formed thickly on the substrate 110 and the light emitting cell 130 of the mesa structure is disposed on the first conductivity type semiconductor layer 120, in contrast, in a light emitting apparatus 100 of FIG. 5, the first conductivity type semiconductor layer 120 may be etched between the light emitting cells 130, so that an upper surface of a substrate 110 may be exposed. Accordingly, lights generated from each of the light emitting cells 130 are seen as distinct from one another, allowing a light-emitting pattern to appear in a matrix form.

Next, FIG. 6A is a light emitting apparatus 200 according to another embodiment, which may be configured identically or similarly to the light emitting apparatus 100 of FIGS. 2 through 4C except for a number and an arrangement of light emitting cells 130.

The light emitting apparatus 200 of FIG. 6A includes a larger number of light emitting cells 130, and the light emitting cells 130 may be disposed in a 4×7 matrix pattern. A number of rows and columns in the matrix pattern is not limited, and the light emitting cells 130 may be disposed in an M×N (M, N are 1 or more) matrix pattern.

Next, FIG. 6B is a light emitting apparatus 300 according to another embodiment, and differences from the light emitting apparatus 100 of FIGS. 2 through 4C will be described.

In a light emitting cell 300 of the light emitting apparatus 300, a light-emitting region ER may be configured in a rectangular shape in which a length of a first direction is longer than a length of a second direction perpendicular to the first direction. This is exemplary, and it is obvious that the emitting region ER may be configured in a rectangular shape in which a length of the first direction is shorter than a length of the second direction perpendicular to the first direction.

In addition, in the light emitting apparatus 300, a second electrode 170 may include only one second finger electrode 174. That is, the second finger electrode 174 does not need to be provided in a plurality of numbers, and it is sufficient when at least one is provided. The second finger electrode 174 may be disposed at an outermost portion of a non light-emitting region or may be disposed between adjacent first finger electrodes 164.

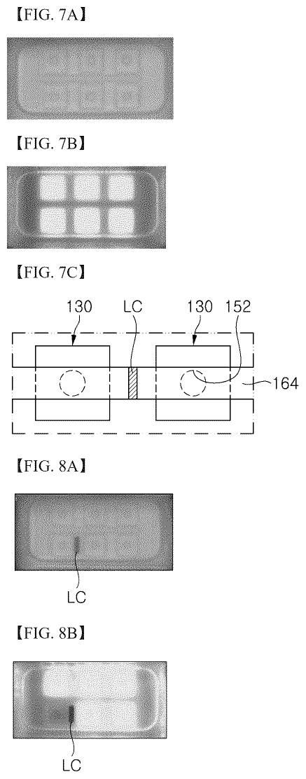

FIG. 7A is a real photograph showing the light emitting apparatus 100 of FIGS. 2 through 4C, in which the light-emitting region ER of each of the light emitting cells 130 is depicted separately in a turned-off state of the light emitting apparatus 100.

FIG. 7B is a diagram illustrating the light emitting apparatus 100 of FIG. 7A in a turned-on state, and it can be seen that each of the light emitting cells 130 is distinguished and a matrix-shaped light-emitting pattern appears from one light emitting cell 130.

Since one light emitting apparatus 100 includes the plurality of light emitting cells 130, some of light emitting cells 130 may be controlled not to be turned on, and through this, it is possible to control the matrix-shaped light emitting pattern. For example, the light emitting pattern may be changed by turning off some light emitting cells 130 such that only the light emitting cells 130 that a user wants to turn on are turned on. Alternatively, some of the light emitting cells 130 may be turned off to control a current density or voltage applied to the light emitting cells 130.

Alternatively, at least one light emitting cell 130 may not be turned on normally due to a defect, which may affect an operation of other light emitting cells 130, thereby making it impossible to use an entire light emitting apparatus 100 as a good product. That is, even when only some of the light emitting cells 130 are defective, the entire light emitting apparatus 100 must be replaced, which may be very inefficient in terms of production cost and time, and thus, the light emitting apparatus 100 according to the present disclosure may greatly improve productivity by ensuring the entire light emitting apparatus 100 to operate normally even when some of the light emitting cells 130 are defective.

Specifically, the first finger electrode 164 of the light emitting apparatus 100 may include a blocking region LC for blocking electrical connection between adjacent light emitting cells 130.

The blocking region LC is configured to block a current path through the first finger electrode 164, and various configurations are possible. For example, the blocking region LC may be an open region where the first finger electrode 164 is disconnected. The blocking region LC may be formed by removing one region of the first finger electrode 164 using a laser or other physical means.

One light emitting apparatus 100 may include one blocking region LC, or may include a plurality of blocking regions LC in different forms.

Referring to FIG. 7C, since the blocking region LC is a configuration that blocks current movement through the first finger electrode 164, current can flow from the first connection electrode 162 to the blocking region LC, but current cannot flow from the blocking region LC to an end of the first finger electrode 164. Accordingly, the blocking region LC may block the light emitting cell 130 disposed after the blocking region LC from being turned on.

The blocking region LC may be disposed between one light emitting cell 130 and an adjacent light emitting cell 130. Accordingly, it is possible to prevent metal particles that may exist in the blocking region LC from moving to the turned-on light emitting cell 130 and increasing a voltage of the light emitting cell 130. In addition, it is possible to prevent the light emitting cell 130 from being damaged during a process of forming the blocking region LC.

As an example, FIG. 8A is a real photograph showing an example in which one blocking region LC is formed on the first finger electrode 164. As a case that one light emitting cell 130 is disposed from the blocking region LC to an end of the first finger electrode 164, referring to FIG. 8B, it can be confirmed that when the light emitting apparatus 100 is turned on, a corresponding light emitting cell 130 is not turned on and the other light emitting cells 130 operate normally. Even when one of the six light emitting cells 130 is not turned on, since a size of the light-emitting region ER that one light emitting cell 130 is responsible for is small, a decrease rate of an entire light-emitting region is small, and only remaining light emitting cells 130 are turned on to operate within a normal range, thereby preventing a rapid decrease in the luminous intensity.

In addition, when a particular light emitting cell 130 is defective or has a defect, it is possible to improve productivity and significantly reduce manufacturing costs by allowing only the light emitting cell 130 having a corresponding defect to be turned off through the blocking region LC, instead of replacing an entire light emitting apparatus 100.

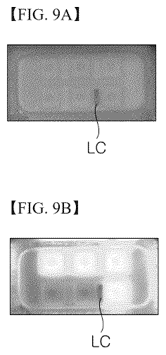

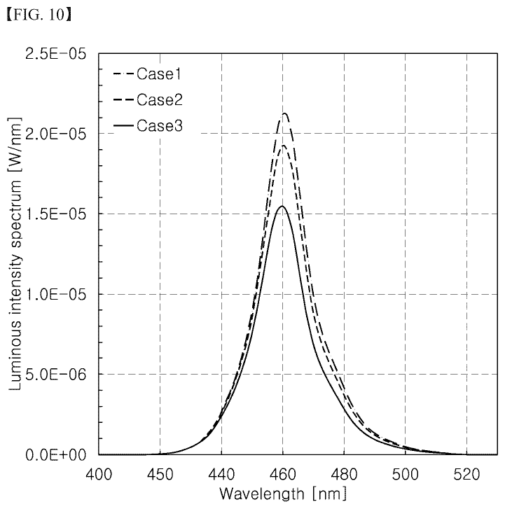

FIG. 9A is a real photograph showing an example in which one blocking region LC is formed on the first finger electrode 164. As a case that two light emitting cells 130 are disposed from the blocking region LC to the end of the first finger electrode 164, referring to FIG. 9B, it can be confirmed that when the light emitting apparatus 100 is turned on, corresponding two light emitting cells 130 are not turned on and the other light emitting cells 130 operate normally.

In a case that at least one of the light emitting apparatuses 100 disposed in the light emitting module 1000 includes the blocking region LC, external quantum efficiencies (EQE) of the light emitting apparatus 100 that does not include the blocking region LC and the light emitting apparatus 100 that has the blocking region LC may be different from each other.

Alternatively, in a case that a same current (A) is applied, a current density (A/cm²) of the light emitting apparatus 100 that does not include the blocking region LC may be higher than a current density (A/cm²) of the light emitting apparatus 100 that has the blocking region LC. Herein, an area of the current density (A/cm²) may be a sum of areas of the light emitting cells 130.

Alternatively, a value of the current density (A/cm²) divided by a number of light emitting cells 130 contributing to lighting may have a smaller value in the light emitting apparatus 100 that does not include the blocking region LC than in the light emitting apparatus 100 that includes the blocking region LC.

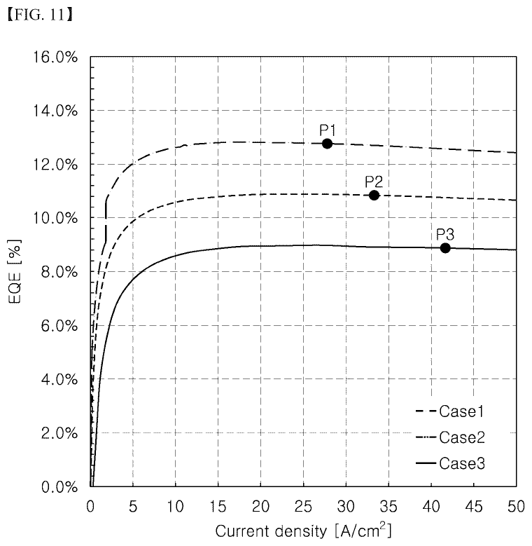

When considering FIGS. 7A and 7B as case 1 in which all light emitting cells 130 are turned on, FIGS. 8A and 8B as case 2 in which one light emitting cell 130 is not turned on, and FIGS. 9A and 9B as case 3 in which two light emitting cells 130 are not turned on, FIG. 10 illustrates luminous intensity spectrums for the cases 1, 2, and 3. Peak wavelengths of light emitted from the light emitting cell 130 in the all cases 1, 2, and 3 are substantially similar.

Referring to FIG. 10, when a same current or voltage is applied, it can be seen that a luminous intensity (W/nm) is a largest in the case 1, followed by the case 2, and finally the case 3.

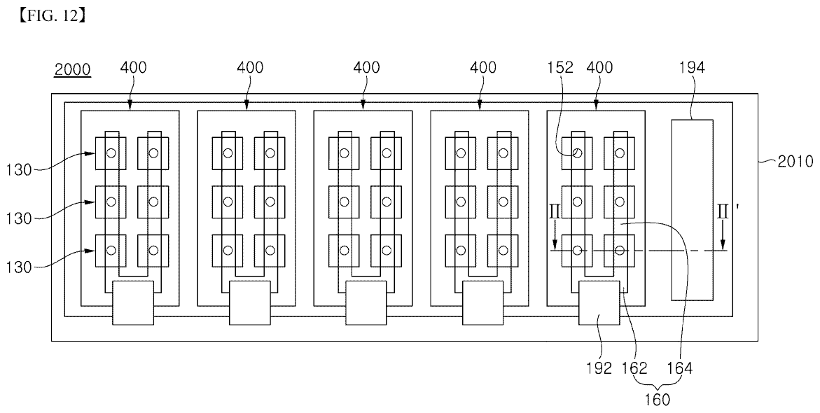

FIG. 11 is a graph showing EQEs (External quantum efficiency) according to current densities (A/cm²) for the cases 1, 2, and 3, and as the number of light emitting cells 130 that are turned on decreases based on a same current density (A/cm²), the EQE decreases. As a number of turned-off light emitting cells 130 in the light emitting apparatus increases, a current density (A/cm²) applied to each single light emitting cell 130 may increase.

Meanwhile, the above described light emitting apparatuses 100, 200, and 300 and light emitting module 1000 may be modified in various ways.

As an example, FIG. 12 is a light emitting module 2000 according to another embodiment of the present disclosure, which may include a plurality of light emitting apparatuses 400. In this case, the light emitting module 2000 may include a substrate 2010 and the plurality of light emitting apparatuses 400 disposed on an upper side of the substrate 2010. The light emitting module 2000 may further include a cover layer 401 covering the plurality of light emitting apparatuses 400.

The light emitting apparatus 400 may be configured identically or similarly to the above described light emitting apparatuses 100, 200, and 300 except for an arrangement of a second electrode 170.

Referring to FIG. 13, the second electrode 170 may be disposed between a substrate 110 and a first conductivity type semiconductor layer 120. That is, the second electrode 170 may be disposed under the first conductivity type semiconductor layer 120 rather than disposed over the first conductivity type semiconductor layer 120 and connected to a second electrode pad 194. The second electrode 170 may be connected to the second electrode pad 194 through an open hole 402 formed in the cover layer 401.

The second electrode pad 194 may be a common electrode pad connected to all of the plurality of light emitting apparatuses 400.

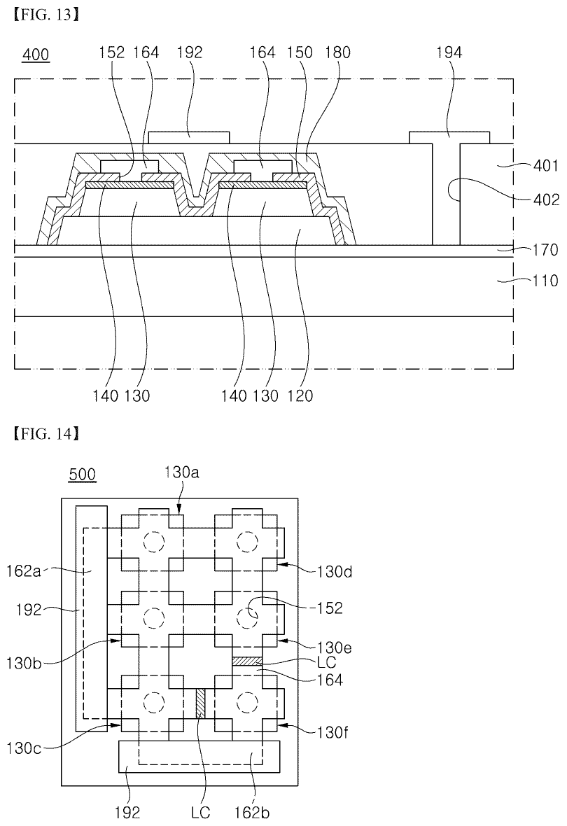

The light emitting apparatus 400 of FIG. 12 may also be modified in various ways. As an example, FIG. 14 illustrates a light emitting apparatus 500 that is a modified example of the light emitting apparatus 400 of FIG. 12. The light emitting apparatus 500 may be configured to be identical or similar to the other light emitting apparatuses 100, 200, 300, and 400 except for a shape and an arrangement of a first electrode 160 and a first electrode pad 192.

In FIG. 14, the first electrode 160 of the light emitting apparatus 500 may be formed in a mesh shape passing over a light emitting cell 130. Specifically, the first finger electrode 164 may be formed in a mesh shape passing over the upper portions of the light-emitting regions ER.

In FIGS. 12 and 13, since the second electrode 170 is formed under the first conductivity type semiconductor layer 120, the first finger electrode 164 of the first electrode 160 may be formed in a mesh shape crossing the plurality of light-emitting regions ER.

Unlike the other light emitting devices 100, 200, 300, and 400 in which the first finger electrode 164 is formed to extend only in the first direction, the first finger electrode 164 of the light emitting apparatus 500 of FIG. 14 is formed in the mesh shape crossing the upper portions of the light emitting cells 130, so that even when a blocking region LC is formed, a path for current to bypass may be secured, and an electrical connection to the light emitting cells 130 to be turned on may be prevented from being blocked.

In a case of the light emitting device 500 of FIG. 14, since the first finger electrode 164 is formed in the mesh shape to cross the light emitting cells 130, by forming the blocking region LC, electrical connection may be blocked by targeting only a particular light emitting cell 130 with a defect. Specifically, in a case that electrical blocking is required for a sixth light emitting cell 130f among first through sixth light emitting cells 130a through 130f in FIG. 14, a blocking region LC may be formed in regions connected to the sixth light emitting cell 130f among the first finger electrodes 164. Accordingly, only a lighting of the sixth light emitting cell 130f may be blocked without affecting lighting operations of the other first to fifth light emitting cells 130a though 130e.

In this case, the first electrode 160 may include a plurality of first electrode pads 192 connected to the first finger electrode 164.

As the first finger electrode 164 is formed in the mesh shape, first connection electrodes 162a and 162b are also provided in a plurality of numbers, so that a difference in length of a current path to each of the light emitting cells 130 may be compensated for. For example, when the sixth light emitting cell 130f is blocked, the fifth light emitting cell 130e adjacent to the sixth light emitting cell 130f may receive current through another first connection electrode 162a adjacent to the fifth light emitting cell 130e.

The first electrode pad 192 may be commonly connected to the first connection electrodes 162a and 162b or may be provided for each of the first connection electrodes 162a and 162b. That is, the first electrode pad 192 may also be provided in a plurality of numbers. The first electrode pads 192 may be disposed on adjacent side surfaces of the light emitting apparatus 500 or may be disposed on side surfaces opposite to each other.

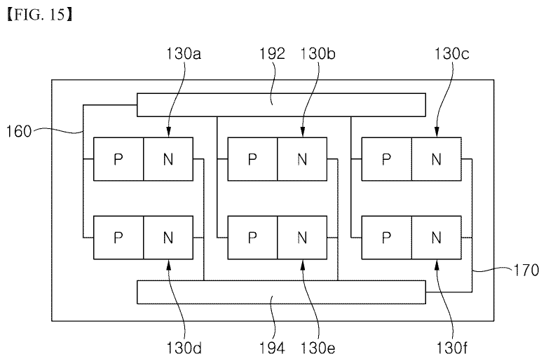

FIG. 15 is a conceptual diagram illustrating electrical connections for the light emitting cells 130a through 130f of the light emitting apparatus 500 of FIG. 14. Since each of the light emitting cells 130a through 130f is independently connected to the first electrode pad 192 and the second electrode pad 194 through separate electrical connection lines, even if a blocking region LC is formed in a portion of the first finger electrode 164, light emitting cells 130 unrelated thereto may still be turned on.

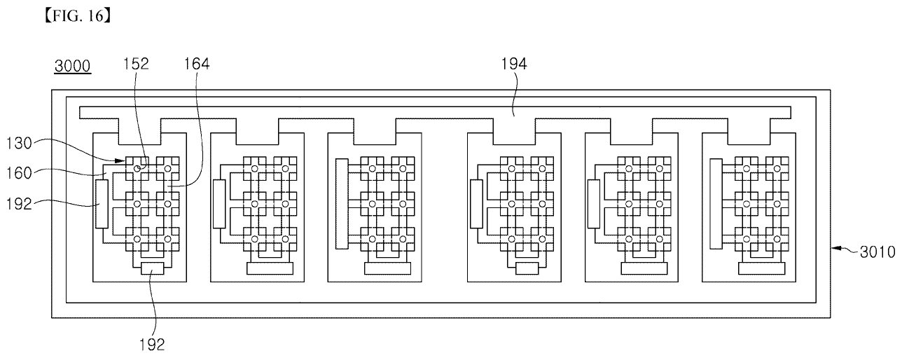

The light emitting apparatus 500 of FIG. 14 may also be modified in various ways, and as shown in FIG. 16, it may be provided in a plurality of numbers to form a light emitting module 3000.

FIG. 16 illustrates the light emitting module 3000 according to another embodiment of the present disclosure, in which the light emitting module 3000 may include a substrate 3010 and a plurality of light emitting apparatuses 600 disposed on the substrate 3010. The light emitting module 3000 may further include a cover layer 601 covering the plurality of light emitting apparatuses 600.

The light emitting apparatus 600 may be configured identically or similarly to the light emitting apparatus 500 of FIG. 14, except for shapes and arrangements of a second electrode 170 and a second electrode pad 194.

In FIG. 16, the second electrode pad 192 may be a common electrode pad connected to a first conductivity type semiconductor layer 120 of all light emitting apparatuses 600.

FIG. 17 is a cross-sectional diagram illustrating the light emitting apparatus 600 of FIG. 16, in which the second electrode 170 may be connected to the first conductivity type semiconductor layer 120 exposed through second openings 154 and 184 of a first insulation layer 150 and a second insulation layer 180. The second electrode 170 may be connected to the second electrode pad 194 through a hole in the cover layer 601.

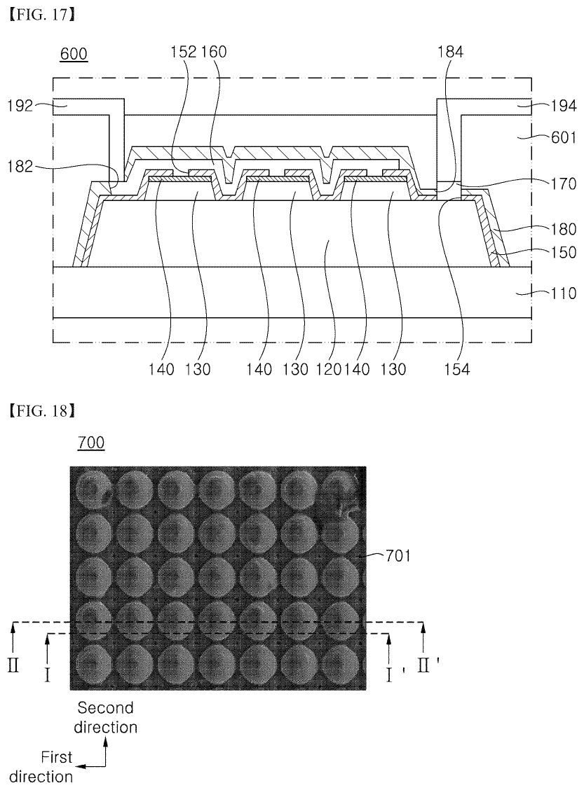

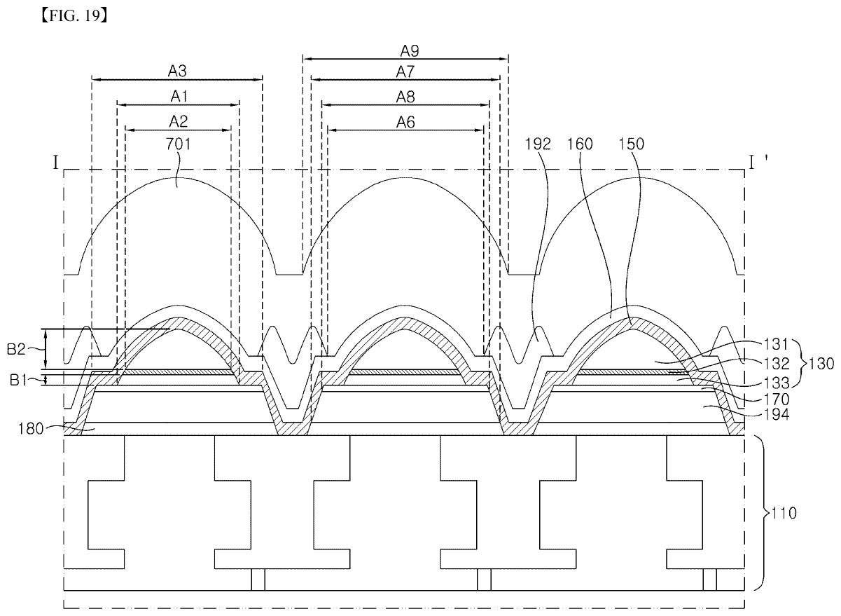

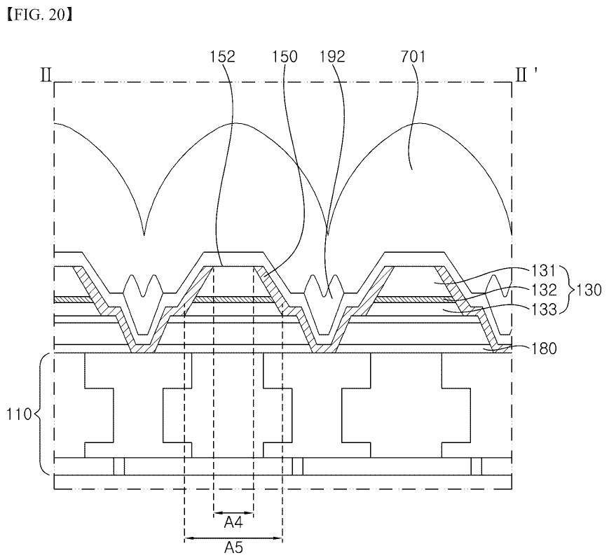

FIG. 18 is a top view illustrating a light emitting apparatus 700 according to another embodiment of the present disclosure, FIG. 19 is a cross-sectional view in a direction I-I′ of FIG. 18, and FIG. 20 is a cross-sectional view in a direction II-II′ of FIG. 18.

The light emitting apparatus 700 may include a plurality of light emitting cells 130 disposed apart from one another on a substrate 110, and a first electrode 160 and a second electrode 170 connected to the plurality of light emitting cells 130.

The substrate 110 is a substrate on which light emitting cells 130 are disposed and is not limited to a particular substrate. For example, the substrate 110 may include a heterogeneous substrate such as a sapphire substrate, a gallium arsenide substrate, a silicon substrate, a silicon carbide substrate, a spinel substrate, a TFT, a circuit board, an IC substrate, or others. Also, the substrate 110 may also include a homogeneous substrate such as a gallium nitride substrate, an aluminum nitride substrate, or others. The substrate 110 may include a conductive pattern, and the conductive pattern may be disposed over the substrate 110, may be disposed within the substrate 110, or may pass through the substrate 110.

The light emitting cells 130 may be a light emitting structure disposed apart from one another on the substrate 110. The light emitting cells 130 may be disposed in a plurality of numbers, and may be disposed in an M×N matrix pattern (M and N are natural numbers) on the substrate 110.

The light emitting cell 130 may be formed protrudingly on the substrate 110. The light emitting cell 130 may include a first conductivity type semiconductor layer 131, an active layer 132, and a second conductivity type semiconductor layer 133.

In one light emitting cell 130, the first conductivity type semiconductor layer 131 may have a shape in which a width thereof becomes variable in a thickness direction. For example, the first conductivity type semiconductor layer 131 may have a shape in which the width thereof gradually decreases as a distance from the active layer 132 increases.

The active layer 132 may be disposed between the first conductivity type semiconductor layer 131 and the substrate 110. Light generated in the active layer 132 may be emitted to the outside through the first conductivity type semiconductor layer 131.

The second conductivity type semiconductor layer 133 may be disposed between the active layer 132 and the substrate 110. The second conductivity type semiconductor layer 133 may have a shape in which a width thereof becomes variable in a thickness direction. For example, the second conductivity type semiconductor layer 133 may have a shape in which the width thereof gradually decreases as a distance from the active layer 132 decreases. Accordingly, in addition to generating light, a lens function extracting light to the outside may also be added to the light emitting cell 130, thereby improving the light extraction efficiency.

In FIG. 19, a maximum width A1 of the second conductivity type semiconductor layer 133 may be greater than a maximum width A2 of the first conductivity type semiconductor layer 131. In addition, a maximum thickness B1 of the second conductivity type semiconductor layer 133 may be smaller than a maximum thickness B2 of the first conductivity type semiconductor layer 131. Accordingly, a resistance of the second conductivity type semiconductor layer 133 may be lowered, thereby reducing a driving voltage and heat generation.

The first electrode 160 may be disposed on the first conductivity type semiconductor layer 131 to be electrically connected to the first conductivity type semiconductor layer 131. The first electrode 160 may be a conductive transparent electrode, and may be, for example, at least one of ITO, ZnO, or IZO. Alternatively, it may be a metallic material, and may be at least one of Au, Ni, Ti, Ag, Pt, Sn, Cu, or Al. The first electrode 160 may cover the light emitting cell 130 and extend to the outside of the light emitting cell 130 to cover a non light-emitting region between the light emitting cell 130 and an adjacent light emitting cell 130, and may cover the adjacent light emitting cell 130. Accordingly, one light emitting cell 130 and the adjacent light emitting cell 130 may be electrically connected through the first electrode 160.

A position of a lower surface of the first electrode 160 between one light emitting cell 130 and the adjacent light emitting cell 130 may be positioned lower than a position of a lower surface of the light emitting cell 130. Accordingly, a length of the first electrode 160 is made longer, thereby preventing the first electrode 160 from being short-circuited even when the substrate 110 contracts or expands.

The second electrode 170 may be disposed under the second conductivity type semiconductor layer 133 and may be electrically connected to the second conductivity type semiconductor layer 133. In addition, the second electrode 170 may also be disposed between the second conductivity type semiconductor layer 133 and a second electrode pad 194 which will be described later.

The second electrode 170 may be a conductive transparent electrode, and may be, for example, at least one of ITO, ZnO, or IZO. Alternatively, the second electrode 170 may be a metallic material, and may be at least one of Au, Ni, Ti, Ag, Pt, Sn, Cu, or Al.

A maximum width A3 of the second electrode 170 may be greater than the maximum width A1 of the second conductivity type semiconductor layer 133. Accordingly, both ends of the second electrode 170 may be disposed to extend outward beyond the light emitting cell 130, thereby improving current spreading.

The second electrode 170 may include a same material as that of the first electrode 160.

Meanwhile, a first insulation layer 150 may be disposed between the first electrode 160 and the light emitting cell 130. The first insulation layer 150 may cover the light emitting cell 130 and extend to the outside of the light emitting cell 130 to cover a non-light-emitting region between the light emitting cell 130 and an adjacent light emitting cell 130, and may cover the adjacent light emitting cell 130.

The first insulation layer 150 may include a first opening 152 exposing a portion of the light emitting cell 130. The first opening 152 may be disposed at a position corresponding to each of the light emitting cells 130, and a number of the first openings 152 exposing each of the light emitting cells 130 may be same as a number of light emitting cells 130. The first insulation layer 150 may be an insulation material such as SiO₂, Ti_{O2}, SiNₓ, Al₂O₃, or others.

In one light emitting cell 130, a width A4 of an exposure region of the light emitting cell 130 exposed by the first opening 152 may be smaller than a maximum width A5 of the light emitting cell 130. The maximum width A5 of the light emitting cell 130 may be 2.1 to 2.9 times of the width A4 of the exposure region of the light emitting cell 130 exposed by the first opening 152. Accordingly, it is possible to prevent excessive electron generation, thereby preventing leakage current generation and increasing resistance.

Meanwhile, the light emitting apparatus 700 may further include a first electrode pad 192.

The first electrode pad 192 may be electrically connected to the first electrode 160, and may be electrically connected to the first conductivity type semiconductor layer 131. The first electrode pad 192 may be electrically connected to a plurality of light emitting cells 130. The first electrode pad 192 may be a metallic material, and may include at least one of Au, Ni, Ti, Ag, Pt, Sn, Cu, or Al.

The first electrode pad 192 may be disposed in a non light-emitting region between the light emitting cells 120, and may have a mesh shape in plan view.

The first electrode pad 192 may include an opening exposing the light emitting cell 130, and a minimum width A6 of the opening may be greater than the maximum width A1 of the light emitting cell 130. Accordingly, a loss of emitted light may be reduced. The width of the opening of the first electrode pad 192 may become large toward a thickness direction. Accordingly, a side surface of the opening of the first electrode pad 192 may increase the light extraction efficiency by reflecting light and guiding a path of light. A partial region of the first electrode pad 192 disposed between the light emitting cell 130 and an adjacent light emitting cell 130 may include a concave portion that is concave at a central axis.

A position of a highest point of the first electrode pad 192 may be positioned higher than that of a highest point of the light emitting cell 130. In addition, a position of a lowest point of the first electrode pad 192 may be positioned lower than that of a lowest point of the light emitting cell 130. Accordingly, an emission efficiency of light emitted from a side surface of the light emitting cell 130 may be increased, and light interference between the light emitting cells 130 may be prevented.

The light emitting apparatus 700 may further include the second electrode pad 194. The second electrode pad 194 may be electrically connected to the second electrode 170, and may be electrically connected to the second conductivity type semiconductor layer 133.

The second electrode pad 194 may be plural, and each of the second electrode pads 194 may be electrically connected to each of the light emitting cells 130. The second electrode pad 194 may be disposed between the light emitting cell 130 and the substrate 110, and further, the second electrode pad 194 may be disposed between the second electrode 170 and the substrate 110.

The second electrode pad 194 may be a metallic material, and may include at least one material of Au, Ni, Ti, Ag, Pt, Sn, Cu, or Al. In cross sectional view, a width of the second electrode pad 194 may gradually decrease in a thickness direction. That is, a width A7 of a lower surface of the second electrode pad 194 facing the substrate 110 may be greater than a width A8 of an upper surface of the second electrode pad 194 facing the light emitting cell 130. A thickness of the second electrode pad 194 may be larger than that of the second electrode 170. Accordingly, a heat capacity of the second electrode pad 194 in a lower direction of the second electrode pad 192 may be increased, thereby increasing heat dissipation performance.

A second insulation layer 180 may be disposed under the second electrode 170. A portion of a lower surface of the second electrode 170 may be in contact with the second insulation layer 180, and a portion of the lower surface of the second electrode 170 may be in contact with a conductive material. Accordingly, the light emitting cell 130 may be electrically connected to a control apparatus such as an external power source or a controller such as an IC chip. The second insulation layer 180 may include an insulation material such as SiO₂, TiO₂, SiNₓ, Al₂O₃, or others.

A position of the lower surface of the second electrode 170 may be positioned lower than that of the lower surface of the first electrode 160. In addition, a position of an upper surface of the second electrode 170 may be positioned higher than that of the lower surface of the first electrode 160. Accordingly, by disposing conductive materials to be overlapped laterally, heat dissipation efficiency may be increased.

The first insulation layer 180 may extend from a lower surface of one light emitting cell 130 to a lower surface of an adjacent light emitting cell 130. Accordingly, a bonding strength between the light emitting cells 130 may be increased.

The light emitting apparatus 700 may further include a cover layer 701. The cover layer may be disposed over the light emitting cell 130, and may cover the plurality of light emitting cells 130.

The cover layer 701 may cover an upper surface of the substrate 110. In addition, the first electrode 160, the first electrode pad 192, the second electrode 170, and the second electrode pad 194 may be covered by the cover layer 401.

The first electrode 160 may be disposed between the first insulation layer 150 and the cover layer 701. Accordingly, by disposing the first electrode 160 having a relatively low refractive index between the first insulation layer 150 and the cover layer 701 having relatively high refractive indices, total internal reflection may be reduced, thereby increasing light extraction.

The cover layer 701 may have a shape in which a width thereof gradually decreases in a thickness direction, and an upper surface of the cover layer 701 may be curved. In addition, a lateral width A9 in a curved region of the cover layer 701 may be greater than the maximum width A1 of the second conductivity type semiconductor layer 133. Furthermore, the lateral width A9 of the curved region of the cover layer 701 may be greater than the width A7 of the lower surface of the second electrode pad 194. Accordingly, light refraction and light emission efficiency by the cover layer 701 may be increased.

A thickness of the cover layer 701 may be greater than that of the light emitting cell 130. The thickness of the cover layer 701 may be 2.2 to 3.4 times of that of the light emitting cell 130. Accordingly, moisture infiltration into the light emitting cell 130 may be prevented by a thick cover layer 701.

The cover layer 701 may fill the concave portion of the first electrode pad 192. Accordingly, a bonding strength between the cover layer 701 and the first electrode pad 192 may be increased, thereby preventing the cover layer 701 from being detached.

Although the present disclosure has been described above with reference to preferred embodiments thereof, it shall be understood by those skilled in the art or having ordinary knowledge in the art that various modifications and changes may be made to the present disclosure without departing from the spirit and technical scope of the present disclosure as set forth in the claims below.

Therefore, the technical scope of the present disclosure should not be limited to the contents described in the detailed description of the specification, but should be defined by the scope of the patent claims.

### DESCRIPTION OF REFERENCE NUMERALS

100, 200, 300, 400, 500, 600, 700: light emitting apparatus
1000, 2000, 3000: light emitting module

1. A light emitting apparatus, comprising:
a plurality of light emitting cells disposed apart from one another on a substrate; and
a first electrode and a second electrode connected to the plurality of light emitting cells,
wherein, for a light emitting cell of the plurality of light emitting cells:
the light emitting cell is a mesa including an active layer that generates light, and
a length of a side of a light-emitting region provided on an upper surface of the light emitting cell is 2 to 50 times of a height of the light emitting cell.

2. The light emitting apparatus of claim 1, wherein the plurality of light emitting cells is disposed in an M×N matrix pattern (M and N are natural numbers), and at least a partial region thereof is surrounded by a non-light-emitting region, respectively.

3. The light emitting apparatus of claim 1, further comprising:
a first insulation layer disposed over the plurality of light emitting cells,
wherein the first insulation layer includes a first opening disposed on the light-emitting region.

4. The light emitting apparatus of claim 3, wherein the first insulation layer further includes a second opening disposed on the non-light-emitting region.

5. The light emitting apparatus of claim 3, wherein the first electrode includes a first finger electrode that extends over upper portions of the light-emitting regions and is electrically connected to at least one of the light emitting cells through the first opening.

6. The light emitting apparatus of claim 4, wherein the second electrode is electrically connected to at least one of the light emitting cells through the second opening.

7. The light emitting apparatus of claim 5, wherein the second electrode includes a second finger electrode extending between the light emitting cells.

8. The light emitting apparatus of claim 5, wherein the first finger electrode extends in a first direction parallel to a side of the substrate in a plan view.

9. The light emitting apparatus of claim 7, wherein:
the second finger electrode extends in the first direction parallel to a side of the substrate on a flat surface, and
the first finger electrode and the second finger electrode are alternately disposed along a second direction perpendicular to the first direction.

10. The light emitting apparatus of claim 9, wherein:
the first electrode further includes a first connection electrode disposed at one end of the first direction and connected to the first finger electrode, and
the second electrode is disposed at the other end of the first direction and connected to the second finger electrode.

11. The light emitting apparatus of claim 5, wherein the first opening is formed at a position overlapping an intersection point where two diagonals connecting vertices of the light-emitting region intersect.

12. The light emitting apparatus of claim 11, wherein a width of the first finger electrode is equal to or greater than a diameter of the first opening.

13. The light emitting apparatus of claim 5, wherein a width of the first finger electrode is 0.4 times or less of that of the light-emitting region.

14. The light emitting apparatus of claim 5, further comprising:
a second insulation layer disposed over the first insulation layer,
wherein the second insulation layer includes a first opening exposing a portion of the first electrode.

15. The light emitting apparatus of claim 14, further comprising:
a first electrode pad connected to the first electrode through the first opening.

16. The light emitting apparatus of claim 3, further comprising an ohmic electrode disposed over at least one of the light emitting cells.

17. The light emitting apparatus of claim 5, wherein the first finger electrode is formed in a mesh shape passing over the upper portions of the light-emitting regions.

18. The light emitting apparatus of claim 17, wherein the first electrode includes a plurality of first electrode pads connected to the first finger electrode.

19. The light emitting apparatus of claim 5, wherein the first finger electrode includes a blocking region configured to block an electrical connection between adjacent light emitting cells.

20. A light emitting apparatus, comprising:
a plurality of light emitting cells disposed apart from one another; and
a first electrode and a second electrode connected to the plurality of light emitting cells,
wherein the first electrode includes a blocking region configured to block electrical connection between adjacent light emitting cells.
